(19) United States
(12) Patent Application Publication
(10) Pub. No.: US 2010/0015731 A1
(43) Pub. Date: Jan. 21, 2010

(54) Method of low-k dielectric film repair

(75) Inventors: Seokmin Yun, Pleasonton, CA (US); Mark Wilcoxson, Oakland, CA (US); John M. de Larios, Palo Alto, CA (US)

Correspondence Address: MARTINE PENILLA & GENCARELLA, LLP, 710 LAKEWAY DRIVE, SUITE 200, SUNNYVALE, CA, 94085, US

(73) Assignee: LAM RESEARCH CORPORATION, Fremont, CA (US)

(21) Appl. No.: 11/708,916

(22) Filed: Feb. 20, 2007

(51) Int. Cl. H01L 21/30; H01L 21/306; C23C 16/54

(52) U.S. Cl. 438/4; 156/345.51; 118/728; 257/E21.211

(57) ABSTRACT

An apparatus, system and method for repairing a carbon depleted low-k material in a low-k dielectric film layer includes identifying a repair chemistry having a hydrocarbon group, the repair chemistry configured to repair the carbon depleted low-k material and applying the identified repair chemistry meniscus to the low-k dielectric film layer such that the carbon depleted low-k material in the low-k dielectric film layer is sufficiently exposed to the repair chemistry meniscus substantially repairing the low-k material. The repaired low-k material exhibits substantially equivalent low-k dielectric characteristics of the low-k dielectric film layer.

### CROSS REFERENCE TO RELATED APPLICATIONS

This application is related to U.S. patent application filed Dec. 21, 2006, and entitled “METHOD OF DAMAGED LOW-K DIELECTRIC FILM LAYER REMOVAL”. The disclosure of the related application is incorporated herein by reference for all purposes.

### FIELD OF THE INVENTION

The present invention relates generally to semiconductor substrate processing, and more particularly, to a method and apparatus for repairing a damaged low-k dielectric film layer of the semiconductor substrate during fabrication operations.

### DESCRIPTION OF THE RELATED ART

Integrated Circuit (IC) features have been shrinking in size over the past few decades resulting in tremendous performance improvements in IC chips. This has resulted in increased speed and density of the chip device. The speed of an electrical signal in an IC relies on the switching time of an individual transistor (transistor gate delay) and the signal propagation time between transistors (Resistance-Capacitance delay or RC delay). With the diminishing size of the features and increasing density, RC delay has started playing a more prominent role in the speed of electrical signal in the IC, and hence, on the chip performance. RC delay can be addressed by using highly conductive metals in interconnect wiring to lower resistance and/or using low dielectric constant material in inter level dielectric layers to reduce capacitance. In addition to reducing RC delay, low-k dielectric materials enable consumption of less power and reduce capacitive coupling, also known as crosstalk, between interconnect features.

There are several low-k dielectric materials available with a dielectric constant range between 2.5 and 4.0. The dielectric constant of the low-k dielectric material may be reduced further by doping the low-k dielectric material with carbon and/or by introduction of pores. Introduction of pores, however, create new challenges as they affect material properties such as mechanical strength, thermal stability and adhesion to different substrate layers among others. These material properties determine if the material can withstand the rigors of further substrate processing such as chemical mechanical polishing (CMP), among others.

The ultra-low-k dielectric material separating the features may get physically and chemically damaged by various fabrication operations used in forming features on the substrate, such as, etching, stripping, etc., as the material properties of the ultra-low-k dielectrics are sometimes compromised. During a stripping operation, for example, a stripping plasma used to strip a carbon based photoresist layer formed near a feature, may damage the low-k material that is exposed to the stripping plasma by depleting the carbon from the low-k material. The carbon depletion in the low-k material results in an increase of the dielectric constant in the low-k dielectric film layer contributing to RC delay.

In view of the foregoing, there is a need for effectively repairing any carbon-depleted low-k material and restoring the ultra low-k dielectric constant in the dielectric film layer so that the features formed on the substrate are preserved.

### SUMMARY

The present invention fills the need by providing an improved method and apparatus for repairing a carbon depleted low-k material in a low-k dielectric film layer of a substrate. It should be appreciated that the present invention can be implemented in numerous ways, including as an apparatus and a method. Several inventive embodiments of the present invention are described below.

In one embodiment, a method for repairing a carbon depleted low-k material in a low-k dielectric film layer of a substrate is disclosed. The method includes identifying a liquid chemistry having a hydrocarbon group, the liquid chemistry configured to repair the carbon depleted low-k material and applying an identified liquid chemistry meniscus to the low-k dielectric film layer such that the carbon depleted low-k material in the low-k dielectric film layer is sufficiently exposed to the liquid chemistry meniscus substantially repairing the low-k material. The repaired low-k material exhibits substantially equivalent low-k dielectric characteristics of the low-k dielectric film layer.

In another embodiment, an apparatus for repairing a carbon depleted low-k material in a low-k dielectric film layer of a substrate is disclosed. The apparatus includes a substrate supporting device to receive and support the substrate and a proximity head configured to receive and apply a gas chemistry meniscus between a surface of the substrate and an opposing surface of the proximity head. The gas chemistry meniscus is substantially contained in an area covering at least a portion of a surface of the substrate. The application of the gas chemistry meniscus provides an isotropic exposure of the surface of the substrate to the gas chemistry meniscus such that the carbon depleted low-k material exposed to the gas chemistry meniscus is substantially repaired. The repaired low-k dielectric material exhibits substantially equivalent low-k dielectric characteristics of the low-k dielectric film layer.

In another embodiment of the invention, an apparatus for repairing a carbon depleted low-k material in a low-k dielectric film layer of a substrate is disclosed. The apparatus includes a substrate supporting device configured to support a substrate and a proximity head configured to receive and apply a gas chemistry meniscus between a surface of the substrate and an opposing surface of the proximity head. The gas chemistry contains a hydrocarbon group and is substantially contained in an area covering at least a portion of a surface of the substrate. The application of the gas chemistry meniscus provides an isotropic exposure of the gas chemistry to the surface of the substrate such that the carbon depleted low-k material exposed to the gas chemistry is substantially repaired. The repaired low-k material exhibits substantially equivalent low-k dielectric characteristics of the low-k dielectric film layer. The substrate supporting device is capable of moving the substrate under the proximity head to substantially maintain the gas chemistry meniscus between the surface of the substrate and the opposing surface of the proximity head.

In another embodiment of the invention, an apparatus for repairing a carbon depleted low-k material in a low-k dielectric film layer of a substrate is disclosed. The apparatus includes a substrate supporting device and a brush device. The substrate supporting device is configured to support a substrate disposed thereon and the brush device includes a brush configured to receive and apply a liquid chemistry to a surface of the substrate. The liquid chemistry contains a hydrocarbon group. The application of the liquid chemistry through the brush provides a uniform exposure of the liquid chemistry to the surface of the substrate such that the carbon depleted low-k material exposed to the liquid chemistry is substantially repaired. The repaired low-k material exhibits substantially equivalent low-k dielectric characteristics of the low-k dielectric film layer. The substrate supporting device and the brush device are configured to move the substrate and the brush relative to each other such that substantial amount of the liquid chemistry exposed to the surface of the substrate is capable of repairing the carbon depleted low-k dielectric material in the low-k dielectric film layer.

Other aspects and advantages of the invention will become more apparent from the following detailed description, taken in conjunction with the accompanying drawings, illustrating by way of example the present invention.

### BRIEF DESCRIPTION OF THE DRAWINGS

The invention may best be understood by reference to the following description taken in conjunction with the accompanying drawings. These drawings should not be taken to limit the invention to the preferred embodiments, but are for explanation and understanding only.

FIG. 1A is a simplified schematic diagram illustrating a carbon depleted low-k material in a low-k dielectric film layer.

FIG. 1B illustrates a simplified schematic diagram of a carbon-based photoresist layer formed in a region around a feature formed during a photoresist operation, in one embodiment of the invention.

FIG. 2A is a cross-section view of an apparatus using a proximity head to apply a gas chemistry, in one embodiment of the invention.

FIG. 2B illustrates an expanded view of a concentrated gas application region illustrated in FIG. 2A.

FIG. 2C illustrates an embodiment of the apparatus having a pair of angled nozzles to apply gas/liquid chemistry.

FIG. 2D is an alternate embodiment illustrated in FIG. 2C with the proximity head using a directly perpendicular nozzle.

FIG. 2E is an alternate embodiment of the invention illustrated in FIGS. 2C and 2D with the proximity head having at least one angled nozzle and one directly perpendicular nozzle.

FIGS. 3A through 3D illustrate a simple composition structure of a low-k dielectric film layer, a carbon depleted low-k material and methyl group containing low-k dielectric film layer.

FIG. 4A is a cross-section view illustrating application of a control chemistry to a substrate using dual proximity heads, in one embodiment of the invention.

FIG. 4B is an alternate embodiment of the embodiment illustrated in FIG. 4A.

FIG. 4C is an alternate embodiment of the embodiments illustrated in FIGS. 4A and 4B.

FIG. 5 is a cross-section view of a system employing proximity heads to apply control chemistry, in one embodiment of the invention.

FIG. 6 illustrates a flow-chart of operations involved in repairing a carbon depleted low-k dielectric film layer, in one embodiment of the invention.

### DETAILED DESCRIPTION

Several embodiments for an improved and effective repairing of carbon depleted low-k material in a low-k dielectric film layer of a substrate, will now be described. It will be obvious, however, to one skilled in the art, that the present invention may be practiced without some or all of these specific details. In other instances, well known process operations have not been described in detail in order not to unnecessarily obscure the present invention.

The low dielectric constant of a low-k dielectric layer may be restored by repairing a carbon depleted low-k material in the low-k dielectric film layer. With the current trend of technological advancement of reduced feature size and increased density of features, removing a carbon depleted low-k material from the low-k dielectric film layer poses a significant challenge. Some methods of removing the carbon depleted low-k dielectric material will result in damage to features formed near the carbon depleted low-k material or damage to the underlying copper interconnects or more damage to the low-k dielectric film layer, thereby rendering the features inoperable. However, by carefully treating the carbon depleted low-k material with carbon enriched chemistry, the low-k material can be significantly repaired and the low-k dielectric characteristics restored to the repaired low-k material so that the repaired low-k material exhibits significantly equivalent characteristics of the low-k dielectric film layer.

Careful treatment of the carbon depleted low-k material in a low-k dielectric film layer enables preserving the quality of the features formed on the substrate and the resulting semiconductor products, e.g., microchips. In an embodiment of the invention, the carbon depleted low-k dielectric material formed in the low-k dielectric film layer is repaired by applying a gas chemistry. The gas chemistry is chosen such that it includes a hydrocarbon group and is configured to repair the carbon depleted low-k material. The gas chemistry is applied as a gas chemistry meniscus to the low-k dielectric film layer through a proximity head such that the carbon depleted low-k material in the low-k dielectric film layer is sufficiently exposed to the gas chemistry meniscus to substantially repair the low-k material. The repaired low-k material exhibits substantially equivalent low-k dielectric characteristics of the low-k dielectric film layer. The controlled application and exposure of the gas chemistry enables carbon from the gas chemistry meniscus to be induced into the carbon depleted low-k material, substantially repairing the low-k material. The repaired low-k material substantially exhibits the low-k characteristics of the low-k dielectric film layer.

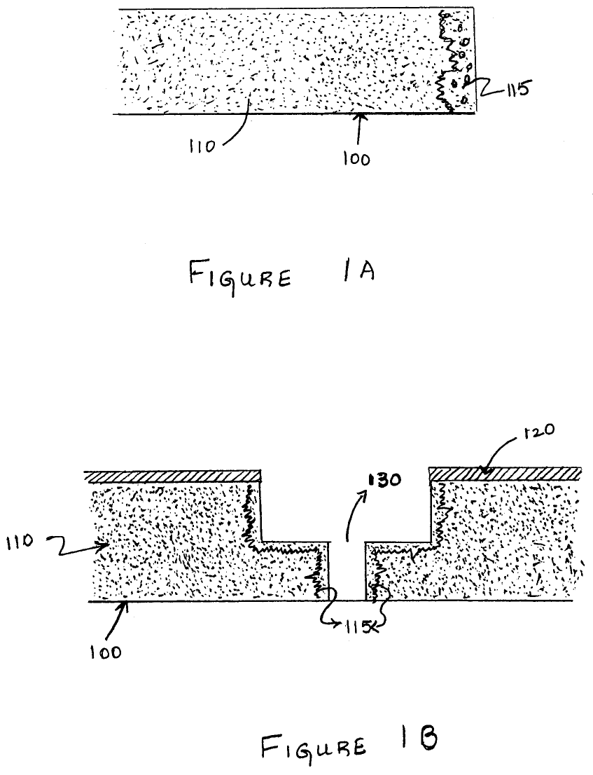

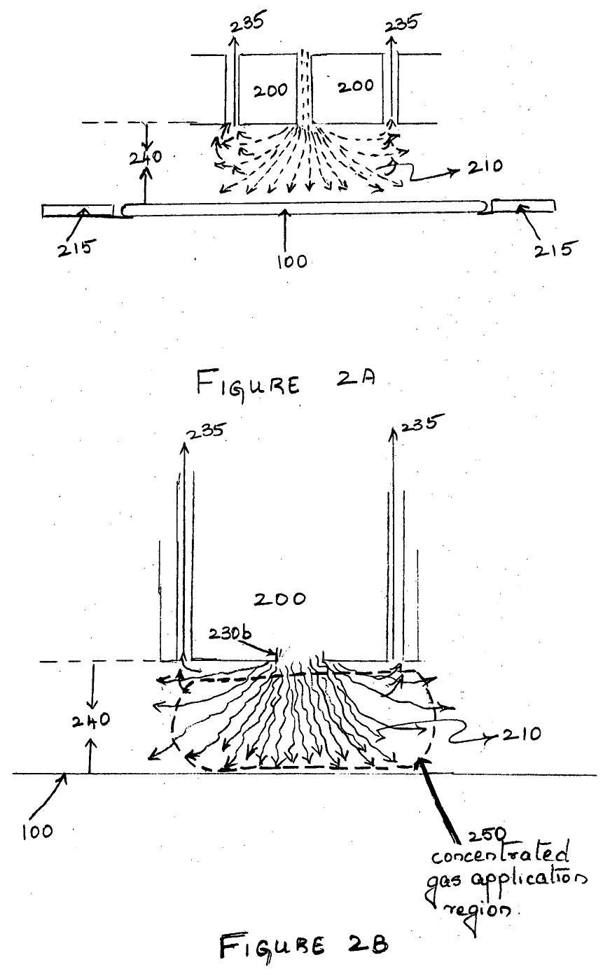

FIG. 1A illustrates a simplified schematic diagram of a carbon depleted low-k material region in a low-k dielectric film layer area. As shown, a low-k dielectric film layer 110 is formed on a substrate 100. The low-k dielectric film layer 110 is formed using any one of spin coating, dip coating, or by a chemical vapor deposition technique. The material used in forming the low-k dielectric film layer can be one of SiCOH, Porous SiCOH, etc. The low-k dielectric material is doped with carbon and a plurality of sub-micron pores are introduced into the low-k dielectric material to further lower the dielectric constant. Pores may be introduced using well-known techniques and is, therefore, not discussed in great detail in this application. The low-k dielectric film layer 110 maybe formed directly over a substrate surface, over previously fabricated layers such as etch stop layer or in-between a plurality of fabricated layers. The low-k dielectric film layer 110 provides insulation to one or more features formed through the low-k dielectric film layer 110 or to the underlying features such as copper interconnects that connect down to transistors formed on the substrate 100. Isolating the features formed on the substrate using low-k dielectric film layer helps in reducing coupling capacitance between features thereby reducing line delay. It is, therefore, essential to retain the low-k dielectric film layer characteristics so that the functionality of the low-k dielectric film layer 110 and of the features 130 and structures are preserved.

During the fabrication process, one or more fabrication layers are formed over the low-k dielectric film layer 110 to create additional features or structures. As shown in FIG. 1B, a feature 130 is formed through a low-k dielectric film layer 110. A carbon-based photoresist layer 120 is formed over the low-k dielectric film layer 110 and the feature 130. During an etching operation following the deposition of the photoresist layer, an etching plasma used to strip part of the carbon-based photoresist layer at or near the feature 130 may cause damage to the low-k dielectric film layer 110 exposed to the etching plasma. This damage may be attributed to the fact that material properties of the low-k dielectric film layer 110 are compromised due to the presence of sub-micron pores. As a result, the carbon doped in the low-k dielectric film layer 110 may easily get depleted from portions of the low-k dielectric film layer 110 exposed to the etching plasma. In one embodiment, repair of the damaged low-k material 115 is performed in order to retain the functionality of the features and structures formed on the substrate 100. Even though FIG. 1B illustrates one embodiment, where the etching operation depletes carbon from the low-k dielectric film layer 110, other fabrication operations may cause similar damage to the low-k dielectric film layer 110. The carbon depleted low-k material 115 exhibits higher dielectric constant in those portions than the rest of the low-k dielectric film layer 110, thereby contributing to line delay. Line delay, also known as RC delay, is defined as a delay in signal propagation between transistors that could be caused by resistance of the materials used in the interconnects and/or the capacitance of the interlevel dielectric layer. In this embodiment, the chemical composition of the low-k dielectric film layer 110 is of the form SiₓO_{y}C_{z}H_{w}, while the composition of the carbon depleted low-k material 115 resembles that of SiₓO_{y}H_{w} due to carbon depletion.

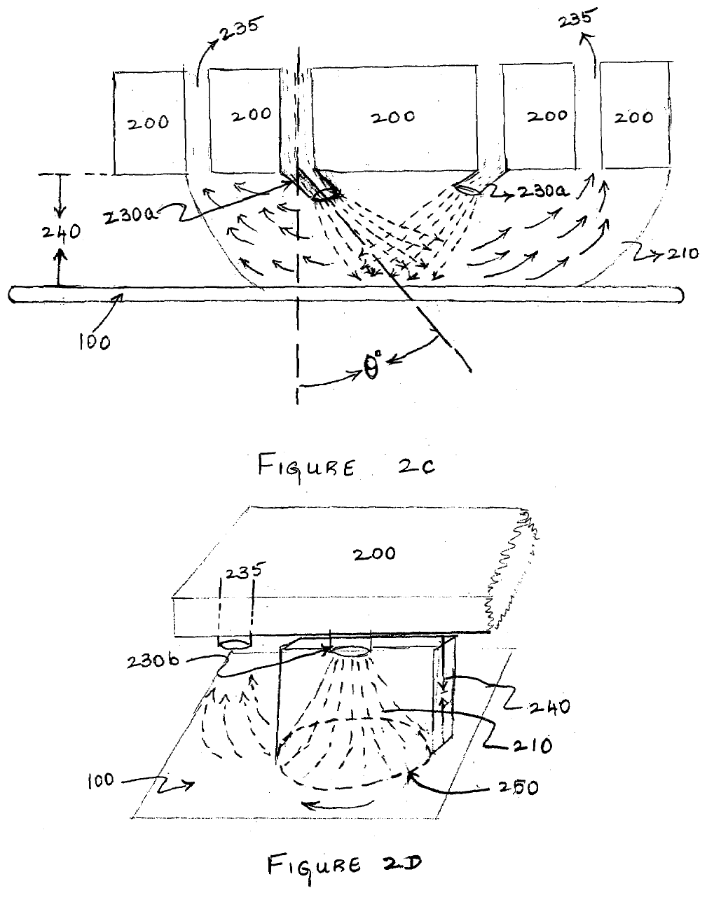

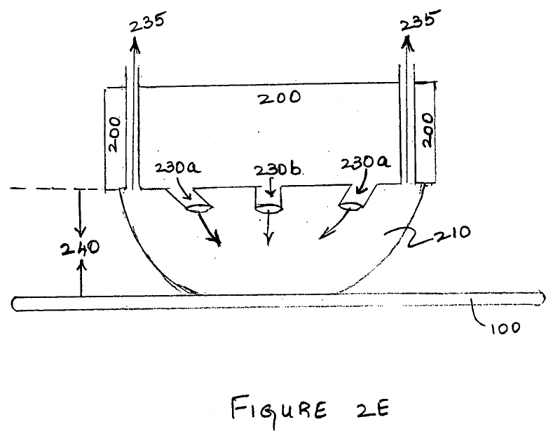

FIG. 2A illustrates a simplified schematic diagram of an apparatus used in providing a gas chemistry meniscus 210 for repairing the carbon depleted (damaged) low-k material 115, in one embodiment of the invention. As shown, a substrate 100 is mounted on a carrier 215. The carrier 215 is configured to receive and hold the substrate 100 in place and to move the substrate 100 along an axis of movement such that different portions of the substrate 100 are exposed to the gas chemistry meniscus 210. The carrier 215 includes pins to receive and hold the substrate 100 in the carrier 215 and along a plane. In one embodiment, motors move the carrier 215 that carry the substrate along the axis of movement, as illustrated in FIG. 2B. The apparatus further includes a proximity head 200 that is configured to deliver a gas chemistry meniscus 210 between a surface of the substrate 100 and an opposing surface of the proximity head 200. The term, “meniscus” as used in the context of a “gas chemistry meniscus”, refers to a volume of “gas” that is applied between the surface of the substrate 100 and the opposing surface of the proximity head 200. The gas chemistry meniscus is substantially gas, but may include liquid in a moisture state. As compared to a fluid meniscus, the gas of the gas chemistry meniscus may not exhibit the tensioactive properties of fluids. Thus, the containment of the gas chemistry meniscus is more local to the point of application and may be more free-flowing. As a result, the applied gas chemistry meniscus may not be completely contained within a containment region, but in one embodiment, its localized application provides a highly concentrated gas to a region that is exposed to gasses flowing from one or more nozzles (of the proximity head). As shown in FIG. 2B, the gas chemistry meniscus provides a highly concentrated gas application region 250. In some cases, some of the gas chemistry may escape the gas application region 250, but the flow can be configured to maintain a level of chemistry concentration in the gas application region 250 to meet the desired treatment levels.

As described herein, a proximity head 200 is a substrate treatment apparatus that can deliver precise volume of a chemistry to a surface of a substrate 100 to be treated, and remove the chemistry from the surface, when the proximity head 200 is placed in close relation to the surface of the substrate 100. In one example, the proximity head 200 has an opposing head surface (opposing surface) and the opposing surface is placed substantially parallel to the surface of the substrate 100. A meniscus is formed between the opposing surface and the surface of the substrate 100. The proximity head 200 may also be configured to deliver a plurality of chemistry, and are configured with vacuum ports 235 for removing the plurality of chemistry that were delivered.

By controlling the delivery and removal of the chemistry to the meniscus, the meniscus can be controlled and moved over the surface of the substrate 100. In some embodiments, the substrate 100 can be moved, while the proximity head 200 is still, and in other embodiments, the proximity head 200 moves and the substrate 100 remains still, during the processing period. Further, for completeness, it should be understood that the processing can occur in any orientation, and as such, the meniscus can be applied to surfaces that are not horizontal (e.g., vertical substrates or substrates that are held at an angle).

For additional information with respect to the proximity head, reference can be made to an exemplary proximity head, as described in the U.S. Pat. No. 6,616,772, issued on Sep. 9, 2003 and entitled “METHODS FOR WAFER PROXIMITY CLEANING AND DRYING.” This U.S. patent application, which is assigned to Lam Research Corporation, the assignee of the subject application, is incorporated herein by reference.

For additional information about the proximity vapor clean and dry system, reference can be made to an exemplary system described in the U.S. Pat. No. 6,488,040, issued on Dec. 3, 2002 and entitled “CAPILLARY PROXIMITY HEADS FOR SINGLE WAFER CLEANING AND DRYING.” This U.S. patent, which is assigned to Lam Research Corporation, the assignee of the subject application, is incorporated herein by reference.

Although FIG. 2A shows a single proximity head 200 for applying the gas chemistry meniscus 210 to a surface of the substrate 100, more than one proximity head may be used to apply the gas chemistry meniscus 210 to one or both surfaces of the substrate 100 for effectively repairing the carbon depleted low-k material.

The gas chemistry meniscus 210 is delivered through one or more nozzles in the proximity head such that at least a portion of the surface of the substrate 100 is exposed to the gas chemistry meniscus 210. The exposure of the gas chemistry meniscus 210 is isotropic in nature which enables uniform application of the gas chemistry meniscus 210 to a portion of the surface of the substrate 100 so that the carbon depleted low-k material exposed to the gas chemistry meniscus 210 is substantially repaired.

In one embodiment illustrated in FIG. 2C, at least one of the nozzles 230a in the proximity head 200 is positioned such that the gas chemistry meniscus 210 is applied at an angle that is between perpendicular and parallel to the surface of the substrate 100. The gas chemistry meniscus 210 is applied such that the flow is substantially parallel to the surface of the substrate 100 and provides an impact on the damaged low-k material 115. The flow of gas chemistry meniscus 210 may be controlled depending on a gap 240 between the surface of the substrate 100 and the opposing head of the proximity head 200. The gap 240, in one embodiment, may be set between about 0.1 mm and about 5 mm, with a mid range between about 0.3 mm and about 1.5 mm. Further, the angling of the nozzle allows the gas chemistry meniscus 210 to be applied and contained within a portion of the substrate 100 relative to the flow or movement of the substrate 100.

In one embodiment, directing the gas toward the center of the proximity head 200 may encourage the gas flow to remain under the proximity head 200, as opposed to flowing away from under the proximity head 200. The angle theta, is in this embodiment, preferably between zero (perpendicular to the surface of the substrate 100) and 90 degrees (parallel to the surface of the substrate 100). In a more specific embodiment, theta is selected to be between about 20 degrees and 45 degrees (pointing toward the center of the proximity head). For nozzles that are located opposite the nozzle with the illustrated theta, the angle is selected in a similar manner.

In another embodiment illustrated in FIG. 2D, at least one of the nozzles 230b of the proximity head 200 is positioned perpendicular to the surface of the substrate 100 such that the gas chemistry meniscus 210 is applied substantially perpendicular to the surface of the substrate 100. The flow rate of the gas chemistry meniscus 210 may be adjusted based on the gap 240 between the surface of the substrate 100 and the opposing surface of the proximity head 200 so as to provide the appropriate impact on the surface of the substrate 100 to facilitate efficient repair of the carbon depleted low-k material 115.

In another embodiment of the invention illustrated in FIG. 2E, the proximity head 200 includes at least one nozzle 230a that is positioned at an angle that is between perpendicular and parallel relative to the surface of the substrate 100, and at least one nozzle 230b that is substantially perpendicular to the surface of the substrate 100. Other variations in the angle and position of the nozzles may be employed so as to provide isotropic exposure of the gas chemistry meniscus 210 to the surface of the substrate 100.

In addition to the one or more nozzles, the proximity head 200 includes a controller to manipulate the flow rate of the gas chemistry meniscus 210 to ensure that fresh material of gas chemistry is sufficiently replenished within the gas chemistry meniscus 210 so that the surface of the substrate 100 is exposed to appropriate amount and quality of gas chemistry meniscus 210 for effective repairing of the carbon depleted low-k material 115.

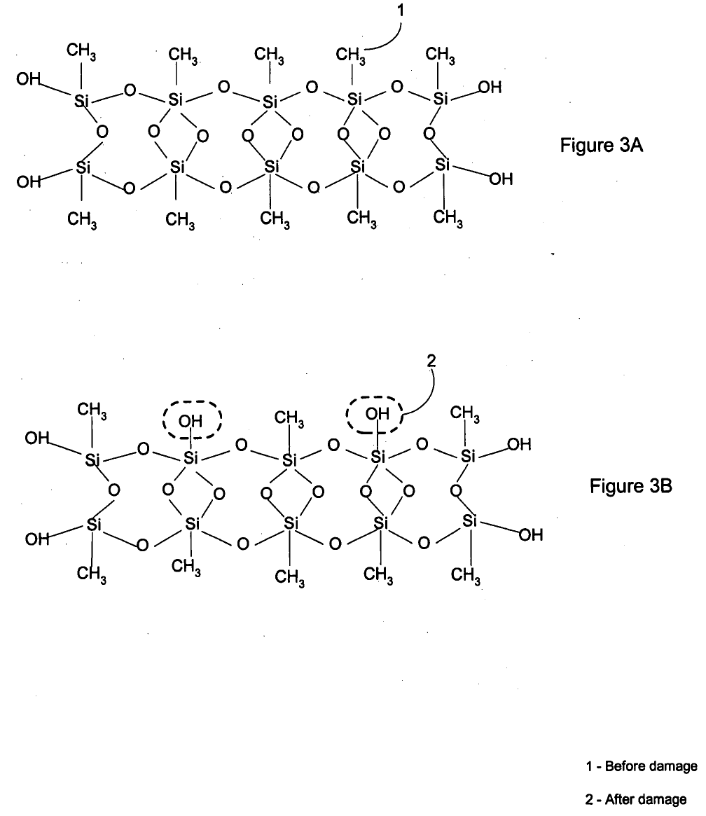

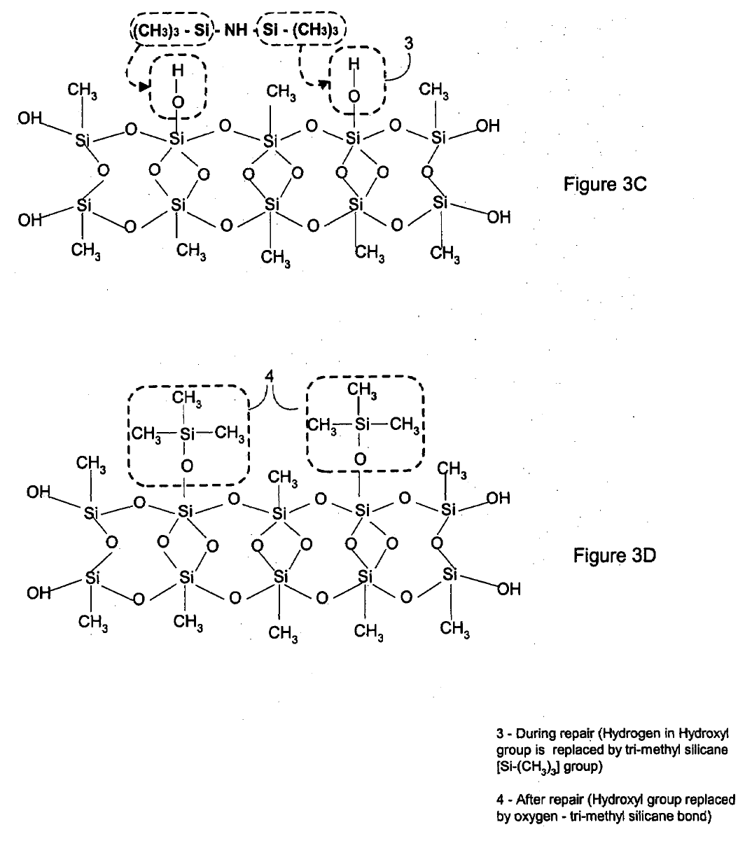

FIG. 3A illustrates a simplified SiₓO_{y}C_{z}H_{w} structure chain that represents the low-k dielectric film layer 110 used in insulating features, structures and other layers prior to the depletion of carbon due to chemicals used in one or more fabrication operations, such as etching/stripping operation. In this embodiment, a methyl group is shown to be directly bonded with each of the silicon in the structure. FIG. 3B illustrates a composition of a damaged low-k material 115 of the low-k dielectric film layer 110 due to carbon depletion after a fabrication operation, in one embodiment of the invention. As can be seen in this embodiment, the composition of damaged low-k material 115 is of the form SiₓO_{y}C_{z-m}H_{w-n} indicating depletion of carbon containing methyl group from the low-k dielectric film layer 110 exposed to the one or more fabrication chemicals. Due to the reaction of one or more fabrication chemicals from a fabrication operation, a silicon-methyl bond of the low-k dielectric film layer 110 is broken and the methyl group is carried away by the etching plasma or fabrication chemical. A hydroxyl group replaces the methyl group by forging a bond with the suspended Silicon. The carbon depleted low-k material 115 exhibits higher dielectric constant and is less hydrophobic than the rest of the low-k dielectric film layer 110.

A gas chemistry in the gas chemistry meniscus 210 is chosen such that the gas chemistry includes at least a hydrocarbon group that can supply carbon to the carbon depleted low-k material 115. The hydrocarbon group of the gas chemistry, in one embodiment, is a methyl group. The repairing of the carbon depleted low-k material is achieved when the gas chemistry, containing a hydrocarbon group such as a methyl group, interacts with the oxygen-hydrogen bond of the hydroxyl group, for example, within the carbon depleted low-k material 115 illustrated in FIG. 3B. In one embodiment illustrated in FIG. 3C, the hydrogen ion of the hydroxyl group of the damaged low-k material 115 is replaced by a methyl containing group of the gas chemistry. In this embodiment, a tri-methyl silicane group is used to supplement the carbon of the damaged low-k material 115. The silicon ion in the tri-methyl silicane group replaces the hydrogen ion in the hydroxyl group forging a bond with the suspended oxygen ion of the hydroxyl group. The resulting structure of the low-k material 115 is illustrated in FIG. 3D wherein the hydrogen ion of the hydroxyl group is replaced by a tri-methyl silicane group of the gas chemistry.

The controller in the proximity head 200 may be used to adjust the flow rate of the gas chemistry so that the induction of the carbon in the carbon depleted low-k material 115 is accomplished. The induction of carbon in the low-k material 115 helps in lowering the dielectric constant of the low-k material thereby restoring the low-k dielectric characteristics to the damaged low-k material 115 that is substantially similar to the characteristics of the low-k dielectric film layer 110.

Although the embodiment illustrated in FIG. 3B indicates the gas chemistry reacting with a hydroxyl bond, the gas chemistry may react with other types of bonds to replace one of the appropriate ions in the bond with carbon from a methyl or other hydrocarbon group, such that the low-k characteristics of the damaged low-k material 115 is restored to a level substantially similar to the low-k dielectric film layer 110. Additionally, the gas chemistry is not restricted to include tri-methyl silicane group but may contain other carbon or methyl containing hydrocarbon group that is capable of inducting carbon into the carbon depleted low-k material 115 substantially repairing the damaged low-k material 115 and restoring the low-k properties to the damaged low-k material 115.

The application of the gas chemistry may be a separate process operation or can be combined with other operations such as cleaning or pre-deposition preparation operation. In one embodiment of the invention, the gas chemistry is alternated with a cleaning chemistry and the two are applied alternatively during a cleaning operation using a single proximity head.

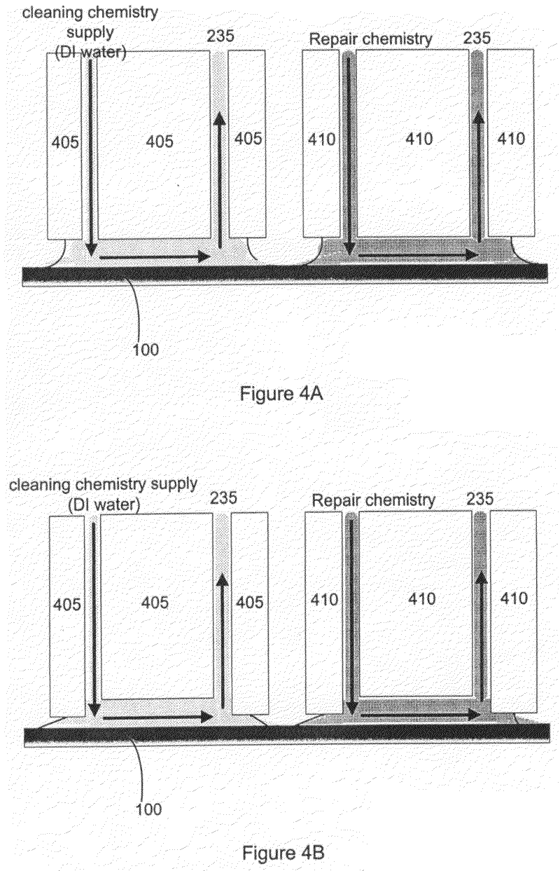

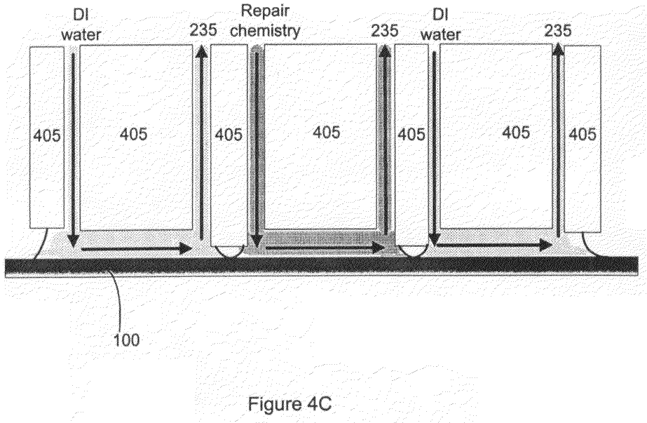

In another embodiment of the invention illustrated in FIG. 4, the apparatus includes two proximity heads 405 and 410, respectively. In this embodiment, the repairing of the carbon depleted low-k material (damaged low-k material) 115 is integrated with a cleaning operation wherein a cleaning chemistry is applied to the surface of the substrate 100 through a first proximity head 405 while the gas chemistry meniscus 210 is applied to the damaged low-k material 115 using the second proximity head 410. The gas chemistry and the cleaning chemistry are removed from the surface of the substrate using vacuum ports 235. The simultaneous application of the gas chemistry meniscus 210 is not restricted to the cleaning operation. The gas chemistry meniscus 210 may be applied to the damaged low-k material 115 simultaneously during other fabrication operation such as pre-deposition preparation, for example.

An alternate embodiment to the apparatus described in reference to FIG. 4A is shown in FIG. 4B. In this embodiment, the dual proximity heads 405 and 410 are configured such that the proximity heads are capable of providing a focused application of gas chemistry 210 to the concentrated gas application region 250. To enable a highly focused gas chemistry application to the surface of the substrate 100, the proximity heads are extended such that they form a pocket into which the gas chemistry is applied as shown in FIG. 4B. The extensions of the proximity head surfaces provide a partial wall that substantially prevents the gas chemistry from escaping out so that a more focused gas chemistry can be applied to the surface of the substrate for effective cleaning.

FIG. 4C illustrates an alternate embodiment of the invention illustrated in FIGS. 4A and 4B. In this embodiment a proximity head 405 is used to apply the repair chemistry to the surface of the substrate. In this embodiment, a meniscus of DI water (or other fluid) is applied on either side of the gas meniscus 150 so that the applied water meniscus acts as a barrier, substantially preventing the gas chemistry from escaping. The applied gas chemistry helps in effectively repairing of the damaged low-k material 115. Although a single proximity head is used in this embodiment, more than one proximity heads may be used to provide the water meniscus on either side of the gas chemistry meniscus. In one embodiment of the invention illustrated in FIG. 4C, the proximity head might be extended to provide a pocket as explained with reference to FIG. 4B. This extended proximity head allows for a more focused application of the gas chemistry to the substrate at the gas application region 250 enabling effective repair of the damaged low-k material 115.

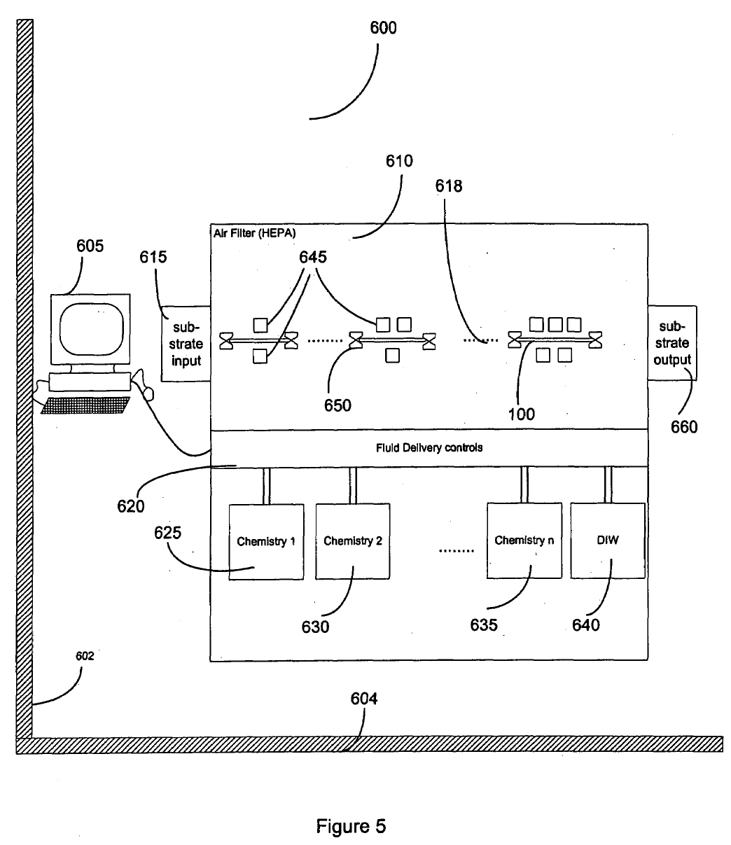

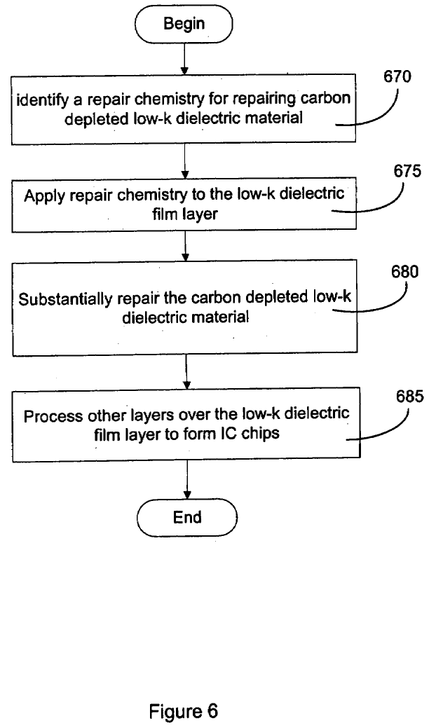

FIG. 5 illustrates a cross-section view of a system within a clean room 600 employing proximity heads used in applying gas chemistry meniscus, a wall 602 and floor 604 of which are shown, in one embodiment of the invention. The system in the clean room (system) 600 includes a housing chamber 610, within which a plurality of proximity heads 645 are located. The proximity heads 645 shown within the housing chamber 610 include dual proximity heads 645 positioned on either side of a processing region 618 through which a substrate 100 moves in the housing chamber 610. Variations of the number and position of proximity heads can be employed. FIG. 6 shows some of the variations, such as dual proximity heads, 3 proximity heads and 5 proximity heads, located on either side of the processing region 618, through which the substrate 100 with carbon depleted low-k material 105 is transported. The substrate 100 is introduced into the housing chamber 610 through a substrate input region 615 and is removed from a substrate output region 660. A carrier 650 positioned in the processing region 618 aids in receiving the substrate through the substrate input region 615, transporting the substrate 100 across the system 600 through the proximity heads 645 and delivering the substrate at the substrate output region 660. The system 600 also includes a set of reservoirs 625, 630, 635, etc. to contain a plurality of chemistries including gas chemistry that are used in repairing the damaged low-k material 115. The system can be employed to apply a variation of gas chemistry, cleaning chemistries and DIW using one or more proximity heads. In one embodiment, the system 600 is used to apply 1) DIW to lightly clean the substrate 100, 2) light Hydrofluoric acid to remove minor contaminants, and 3) gas chemistry to repair the carbon depleted low-k material 115. In other embodiments of the invention, the system 600 may be used to apply 1 and 3 alone or just 3.

The gas and cleaning chemistries are applied to the surface of the substrate 100 in a controlled manner, based on an analysis made of the carbon depleted low-k material 115 to be repaired and the corresponding film layers formed over and under the carbon depleted low-k material 115, using a delivery control mechanism 620. A computer 605 running a software may be communicatively connected to the delivery control mechanism 620 to adjust the controls within the delivery control mechanism 620 so that the gas and cleaning chemistries may be applied to the substrate 100 in a controlled manner. Although the computer 605 is shown to be located within the clean room, the computer 605 can be positioned anywhere outside the clean room and communicatively connected to the delivery control mechanism 620 within the housing chamber 610.

The embodiments of the invention are not restricted to the application of a gas chemistry. In another embodiment of the invention, a liquid chemistry may be used in place of a gas chemistry. In one embodiment, the liquid chemistry is applied as a liquid chemistry meniscus 210′ using a proximity head 200. The term, “meniscus,” as used herein with reference to liquid chemistry, refers to a volume of liquid chemistry bounded and contained in part by surface tension of the liquid chemistry between the opposing surface of a proximity head 200 and a surface of the substrate 100. The meniscus thus formed, is also controllable and can be moved over a surface in the contained shape and is used to remove the contaminants from the surface of the substrate 100. In specific embodiments, the meniscus shape can be controlled by precision liquid chemistry delivery and removal systems that may further include a computing system. The liquid chemistry may contain a hydrocarbon group that works similar to the hydrocarbon group of the gas chemistry. In one embodiment of the invention, the hydrocarbon group of the liquid chemistry is a methyl group and the carbon in the methyl group is used to replenish the depleted carbon in the low-k material 115 restoring the low-k characteristics of the low-k material 115 to a level substantially similar to the low-k dielectric film layer 110.

For information regarding the formation of a meniscus, in liquid form, reference may be made to: (1) U.S. Pat. No. 6,616,772, issued on Sep. 9, 2003 and entitled “METHODS FOR WAFER PROXIMITY CLEANING AND DRYING,”; (2) U.S. patent application Ser. No. 10/330,843, filed on Dec. 24, 2002 and entitled “MENISCUS, VACUUM, IPA VAPOR, DRYING MANIFOLD,” (3) U.S. Pat. No. 6,988,327, issued on Jan. 24, 2005 and entitled “METHODS AND SYSTEMS FOR PROCESSING A SUBSTRATE USING A DYNAMIC LIQUID MENISCUS,” (4) U.S. Pat. No. 6,988,326, issued on Jan. 24, 2005 and entitled “PHOBIC BARRIER MENISCUS SEPARATION AND CONTAINMENT,” and (5) U.S. Pat. No. 6,488,040, issued on Dec. 3, 2002 and entitled “CAPILLARY PROXIMITY HEADS FOR SINGLE WAFER CLEANING AND DRYING,” each is assigned to Lam Research Corporation, the assignee of the subject application, and each is incorporated herein by reference. For additional information about top and bottom menisci, reference can be made to the exemplary meniscus, as disclosed in U.S. patent application Ser. No. 10/330,843, filed on Dec. 24, 2002 and entitled “MENISCUS, VACUUM, IPA VAPOR, DRYING MANIFOLD.” This U.S. patent application, which is assigned to Lam Research Corporation, the assignee of the subject application, is incorporated herein by reference.

In still another embodiment, a spin applicator (similar to an SRD) may be used to receive and hold the substrate. The spin applicator is mounted within a tank that acts as a reservoir to hold the excess liquid chemistry. The spin applicator is configured to rotate along an axis so as to expose different portions of the substrate to a liquid chemistry. In yet anther example, the liquid chemistry may be applied to a surface of the substrate using a proximity head, over a rotating substrate. Accordingly, the way in which the substrate is held is not limited to a carrier, but can take on other ways, so long as the treatment with the gas or liquid chemistry is accomplished.

In another embodiment of the invention, a brush device can be used instead of a proximity head. In this embodiment, a liquid chemistry is identified and the identified liquid chemistry is introduced into a brush. The brush with the liquid chemistry is applied to the carbon depleted low-k material 115 at the low-k dielectric film layer 110 so that the carbon depleted low-k material 115 is substantially repaired. A controller in the brush device may be used to control the flow-rate and other parameters of the liquid chemistry so that the carbon depleted low-k material 115 is substantially exposed to the liquid chemistry for effective repair of the carbon depleted low-k material 115.

A method for repairing a carbon depleted low-k material (damaged material) 115 in a low-k dielectric film layer 110 of a substrate 100 will now be described in detail with reference to FIG. 6. The method begins with identifying a repair chemistry to be applied to a substrate 100 for repairing the damaged material 115, as shown in operation 670. As mentioned earlier, the repair chemistry may be either a gas chemistry or a liquid chemistry that contains a hydrocarbon group. In one embodiment of the invention, the hydrocarbon of the repair chemistry is a methyl group. Portions of a low-k dielectric film layer 110 may get damaged by one or more fabrication operations, such as CMP, etching, photolithography, deposition, etc., that are used in creating features 130, structures or layers. The chemicals used in these operations may react with the carbon doped in the low-k dielectric film layer 110 at regions around the formed features 130, depleting the carbon from the low-k dielectric film layer 110. The carbon depleted low-k dielectric film layer 110 in areas around the features 130 will have a higher dielectric constant than the rest of the low-k dielectric film layer 110, resulting in line delay. The damaged material 115, therefore, needs to be repaired to substantially retain the low-k dielectric characteristics of the dielectric film layer 110.

The repair chemistry is chosen such that the damaged material 115 may be selectively repaired without damaging the surrounding features, structures and layers. Repair chemistry that is used in selectively repairing the damaged material 115 include hydrocarbon groups of the form CₓH_{y}.

In operation 675, the repair chemistry is applied to the low-k dielectric film layer 110 on the substrate 100. The application of the repair chemistry may be through a proximity head 200 or through a brush device and may be controlled using a controller available at the proximity head 200 or the brush device. The controlling of the application of the repair chemistry may depend on one or more parameters of the repair chemistry such as flow rate, temperature, type, etc. The application of the repair chemistry may also depend on the gap 240 between the surface of the substrate 100 and the opposing surface of the proximity head 200 or the angle of the one or more nozzles at the proximity head 200 through which the repair chemistry is introduced as a repair chemistry meniscus 210.

In operation 680, the repair chemistry reacts with the damaged low-k material 115 to replace a oxygen-hydrogen bond with a oxygen-carbon bond, as illustrated in FIG. 3C. The carbon in the hydrocarbon group of the repair chemistry reacts with the oxygen-hydrogen bond in the damaged low-k material 115 replacing the hydrogen in the oxygen-hydrogen bond with the carbon from the hydrocarbon group forming a oxygen-carbon bond. By providing a controlled exposure of the damaged low-k material 115 to the repair chemistry, the damaged low-k material 115 may be substantially repaired thereby preserving the functionality of the features, structures and layers formed on the substrate.

The repair chemistry that have shown promising results in repairing the damaged low-k material 115 include methyl containing hydrocarbons such as Hexamethyldisilazane (HMDS), Trimethyldisilazane (TMDS), Chlorosilanes such as Trimethylchlorosilane (TMCS), Dimethyldichlorosilane (DMDCS), Trimethylchlorosilane ((CH₃)₃Si—Cl), n-Polytrimethylsilane (n-PTMS), combinations of these chemicals, or combinations of these chemicals mixed with other chemicals. The flow-rate of the repair chemistry that has shown promising results is between about 0.2 standard liters per minute (slm) to about 2.5 slm with a mid rage between about 1.0 slm to about 1.5 slm and an optimal flow rate of about 1.5 slm. Other parameters of the repair chemistry may include temperature, concentration, exposure time, etc. The temperature of the repair chemistry ranges between about 20° C. to about 90° C. with a mid range between about 40° C. to about 80° C. Optional high temperature bake can follow after the repair. The temperature for post bake ranges between about 50° C. to about 450° C. with a mid range between about 200° C. to about 400° C. Concentration of repair chemistry that has shown promising results in repairing damaged low-k materials 115 is between about 50% to about 100% of repair chemistry vs. DIW, with a mid range between about 80% to about 99% of repair chemistry vs. DIW. Exposure time that has shown promising results in repairing damaged low-k materials is between about 0.5 second to about 30 seconds with a mid-range of about 1 second to about 10 seconds.

The process continues with operation 685, wherein additional layers and features may be formed over the low-k dielectric film layer 110 to define an integrated circuit chip (IC chip). Some of the additional layers that may be formed include barrier layer, copper film deposit layer to define the metallization interconnects and low-k dielectric film layer, etc. The process may repeat till IC chips are formed on the substrate or some level of fabrication is reached.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. An apparatus for repairing a carbon depleted low-k material in a low-k dielectric film layer of a substrate, comprising:
a substrate supporting device to receive and support the substrate; and
a proximity head configured to receive and apply a gas chemistry meniscus between a surface of the substrate and an opposing surface of the proximity head, the gas chemistry being substantially contained in an area covering at least a portion of a surface of the substrate, the application of the gas chemistry meniscus providing an isotropic exposure of the surface of the substrate to the gas chemistry such that the carbon depleted low-k material exposed to the gas chemistry is substantially repaired, wherein the repaired low-k material exhibiting substantially equivalent low-k dielectric characteristics of the low-k dielectric film layer.

2. The apparatus of claim 1, wherein the gas chemistry is applied in a controlled volume between the surface of the substrate and the surface of the proximity head, the controlled volume establishing a gas application region that can be controllably moved to different locations over the surface of the substrate.

3. The apparatus of claim 1, wherein the gas chemistry is introduced between the surface of the substrate and a surface of the proximity head through one or more nozzles.

4. The apparatus of claim 3, wherein at least one nozzle is directed such that the gas chemistry is applied substantially perpendicular to the surface of the substrate.

5. The apparatus of claim 3, wherein at least one nozzle is angled such that the gas chemistry is applied at an angle that is between perpendicular and parallel to the surface of the substrate.

6. The apparatus of claim 3, wherein the gas chemistry includes at least a hydrocarbon group.

7. The apparatus of claim 6, wherein the hydrocarbon group includes a methyl group.

8. The apparatus of claim 6, wherein the proximity head includes a controller to manipulate a flow rate of the gas chemistry such that fresh material of gas chemistry is sufficiently replenished between the surface of the substrate and the opposing surface of the proximity head.

9. The apparatus of claim 1, wherein the proximity head further comprising a distinct portion for generating a cleaning chemistry meniscus at the surface of the substrate, such that the cleaning chemistry substantially removes residues left from one or more fabrication operations prior to repairing the carbon depleted low-k dielectric material.

10. The apparatus of claim 1, further comprising a second proximity head, the second proximity head generating a cleaning chemistry meniscus at the surface of the substrate such that the cleaning chemistry substantially removes residues left from one or more fabrication operations prior to repairing the carbon depleted low-k dielectric material.

11. The apparatus of claim 3, wherein the proximity head further comprising extensions on either side of the nozzle, the extensions of the proximity head providing a pocket within which the applied gas chemistry is substantially contained, the pocket defining a treatment region such that it provides a more focused application of the gas chemistry to the surface of the substrate.

12. The apparatus of claim 1, wherein the proximity head further comprising
distinct portions for applying de-ionized water menisci to the surface of the substrate, such that the applied de-ionized water menisci provide a treatment region within which the applied gas chemistry meniscus is substantially contained, the contained gas chemistry meniscus providing an isotropic exposure of the surface of the substrate to the gas chemistry such that the carbon depleted low-k material exposed to the gas chemistry is substantially repaired.

13. A method for repairing a carbon depleted low-k material in a low-k dielectric film layer of a substrate, comprising:
identifying a repair chemistry having a hydrocarbon group, the repair chemistry configured to repair the carbon depleted low-k material; and
applying the repair chemistry as a meniscus to the low-k dielectric film layer such that the carbon depleted low-k material in the low-k dielectric film layer is sufficiently exposed to the repair chemistry substantially repairing the low-k material, the repaired low-k material exhibiting substantially equivalent low-k dielectric characteristics of the low-k dielectric film layer, the repair chemistry is administered as a meniscus through a proximity head.

14. The method for repairing a carbon depleted low-k material in a low-k dielectric film layer of a substrate of claim 13, wherein the hydrocarbon group includes a methyl group.

15. The method for repairing a carbon depleted low-k material in a low-k dielectric film layer of a substrate of claim 13, wherein application of the repair chemistry is by adjusting a flow rate of the repair chemistry, the flow rate configured to deliver and remove repair chemistry so as to substantially maintain the repair meniscus over the surface of the substrate.

16. The method for repairing a carbon depleted low-k material in a low-k dielectric film layer of a substrate of claim 15, wherein the flow rate of the repair chemistry is based on a gap between a surface of the proximity head and a surface of the substrate.

17. The method for repairing a carbon depleted low-k material in a low-k dielectric film layer of a substrate of claim 16, wherein the flow of the repair chemistry is sufficiently parallel to the surface of the substrate.

18. An apparatus for repairing a carbon depleted low-k material in a low-k dielectric film layer of a substrate, comprising:
a substrate supporting device configured to support a substrate disposed thereon; and
a proximity head configured to receive and apply a gas chemistry meniscus between a surface of the substrate and an opposing surface of the proximity head, the gas chemistry containing a hydrocarbon group substantially contained in an area covering at least a portion of a surface of the substrate, the application of the gas chemistry meniscus providing an isotropic exposure of the gas chemistry to the surface of the substrate such that the carbon depleted low-k material exposed to the gas chemistry is substantially repaired, the repaired low-k material exhibiting substantially equivalent low-k dielectric characteristics of the low-k dielectric film layer,
wherein the substrate supporting device capable of moving the substrate relative to the proximity head to substantially maintain gas chemistry meniscus between surface of the substrate and the opposing surface of the proximity head.

19. The apparatus for repairing a carbon depleted low-k material in a low-k dielectric film layer of a substrate of claim 18, wherein the hydrocarbon group includes a methyl group.

20. An apparatus for repairing a carbon depleted low-k material in a low-k dielectric film layer of a substrate, comprising:
a substrate supporting device configured to support a substrate disposed thereon; and
a brush device including a brush configured to receive and apply a liquid chemistry on a surface of the substrate, the liquid chemistry containing a hydrocarbon group, the application of the liquid chemistry through the brush providing an uniform exposure of the liquid chemistry to the surface of the substrate such that the carbon depleted low-k material exposed to the liquid chemistry is substantially repaired, the repaired low-k material exhibiting substantially equivalent low-k dielectric characteristics of the low-k dielectric film layer,
wherein the substrate supporting device and the brush device are configured to move the substrate and the brush relative to each other such that the liquid chemistry is capable of repairing the carbon depleted low-k dielectric material in the low-k dielectric film layer.
